(19) United States
(12) Patent Application Publication
(10) Pub. No.: US 2013/0178068 A1
(43) Pub. Date: Jul. 11, 2013

(54) DUAL DAMASCENE PROCESS AND APPARATUS

(71) Applicants: Chai Der YEN, Tainan City (TW); Fu-Cheng CHANG, Tainan City (TW); Cheng-Pang YEH, Tainan City (TW); Hung-Yu CHIU, Tainan City (TW); Hung-Che LIAO, Tainan City (TW)

(72) Inventors: Chai Der YEN, Tainan City (TW); Fu-Cheng CHANG, Tainan City (TW); Cheng-Pang YEH, Tainan City (TW); Hung-Yu CHIU, Tainan City (TW); Hung-Che LIAO, Tainan City (TW)

(73) Assignee: TAIWAN SEMICONDUCTOR MANUFACTURING CO., LTD., Hsin-Chu (TW)

(21) Appl. No.: 13/346,781

(22) Filed: Jan. 10, 2012

(51) Int. Cl. H01L 21/302; G03F 1/00

(52) U.S. Cl. 438/700; 430/5; 257/E21.214

(57) ABSTRACT

A method comprising providing at least one dielectric layer above a semiconductor substrate, the at least one dielectric layer having a top surface and a bottom surface; forming a photoresist layer on the top surface of the at least one dielectric layer; providing a single photomask having at least one first pattern corresponding to a conductive via and at least one second pattern corresponding to a conductive trace; patterning the photoresist layer using the single photomask, for forming a trench in the photoresist corresponding to the conductive trace and an opening in a bottom surface of the trench corresponding to the via with a single photo exposure step; and etching the dielectric through the photoresist layer to form the trench and via therein. This application also relates to photomasks for use in the methods of this application.

### FIELD

The present application relates, most generally, to methods of forming an opening in a dual damascene process and to a photomask for use in forming an opening in a dual damascene process.

### BACKGROUND

Semiconductor fabrication is widely applied in electronic devices. In such fabrication, a photomask is used to provide a defined geometric pattern in a semiconductor wafer. As many as twenty or more masks may be used in the semiconductor fabrication process. For example, a given semiconductor process may use a p-well, n-well, active, poly, p-select, n-select, contact, and/or metal 1, 2, 3 . . . masks. Also, back-end-of-line (“BEOL”) processes use photomasks to create networks of metal interconnects between devices, such as transistors, capacitors, resistors, and the like. A BEOL process forms interconnect wires, dielectric structures, trenches, and vias, which are used to connect layers in a semiconductor wafer. As the use of copper interconnects in semiconductor fabrication grows, the dual damascene process has become more prominent because it allows the creation of both vias and trenches in a single dielectric layer.

The dual damascene process is currently conducted in two ways. First, a trench may be formed in a multi-layered structure using a photomask. The trench is plugged using a photoresist material. Then another photomask and another round of photolithography or photo-etching forms a via opening. Alternatively, a via opening may be first formed in a via layer using a photomask. Then the via opening is plugged using a photoresist material. Another photomask is then used and another round of photolithography or photo-etching forms a trench. Once the photoresist plug is removed from either the trench or via openings, these openings can then be filled with copper or other conductive materials by sputtering and planarized by chemical mechanical polishing (“CMP”).

### BRIEF DESCRIPTION OF THE DRAWINGS

The present application is best understood from the following detailed description when read in conjunction with the accompanying drawings. It is emphasized that, according to common practice, the various features of the drawings are not necessarily to scale. On the contrary, the dimensions of the various features are arbitrarily expanded or reduced for clarity. Like numerals denote like features throughout the specification and drawings.

FIGS. 1A-D are schematic cross-sectional views of an exemplary method of forming an opening in a dual damascene structure.

FIGS. 2A-E are schematic cross-sectional views of an exemplary method of forming an opening in a dual damascene structure.

FIGS. 3-4 are cross-sectional views of exemplary photomasks used to form an opening in a dual damascene structure.

FIGS. 5A-D are perspective views from the top side of exemplary photomasks for forming an opening in a dual damascene structure.

### DETAILED DESCRIPTION

The details of one or more embodiments of the invention are set forth in the accompanying drawings and the description below. Other features, objects, and advantages of the invention will be apparent from the description and drawings, and from the claims. In the description, relative terms such as “lower,” “upper,” “horizontal,” “vertical,” “above,” “below,” “up,” down,” “top,” “bottom,” “length-wise,” “width-wise” as well as derivatives thereof should be construed to refer to the orientation as then described or as shown in the drawing under discussion. These relative terms are for convenience of description and do not require that the structure be construed in a particular orientation.

The present application relates to simplified dual damascene processes and photomasks for use in such processes. According to various embodiments, a single photomask is used to form a trench in a photoresist and an opening at the bottom of the trench in the photoresist using a single photo process. The photoresist provides a single hardmask that is subsequently used for forming a via layer and an adjacent line layer in an intermetal dielectric (“IMD”) material.

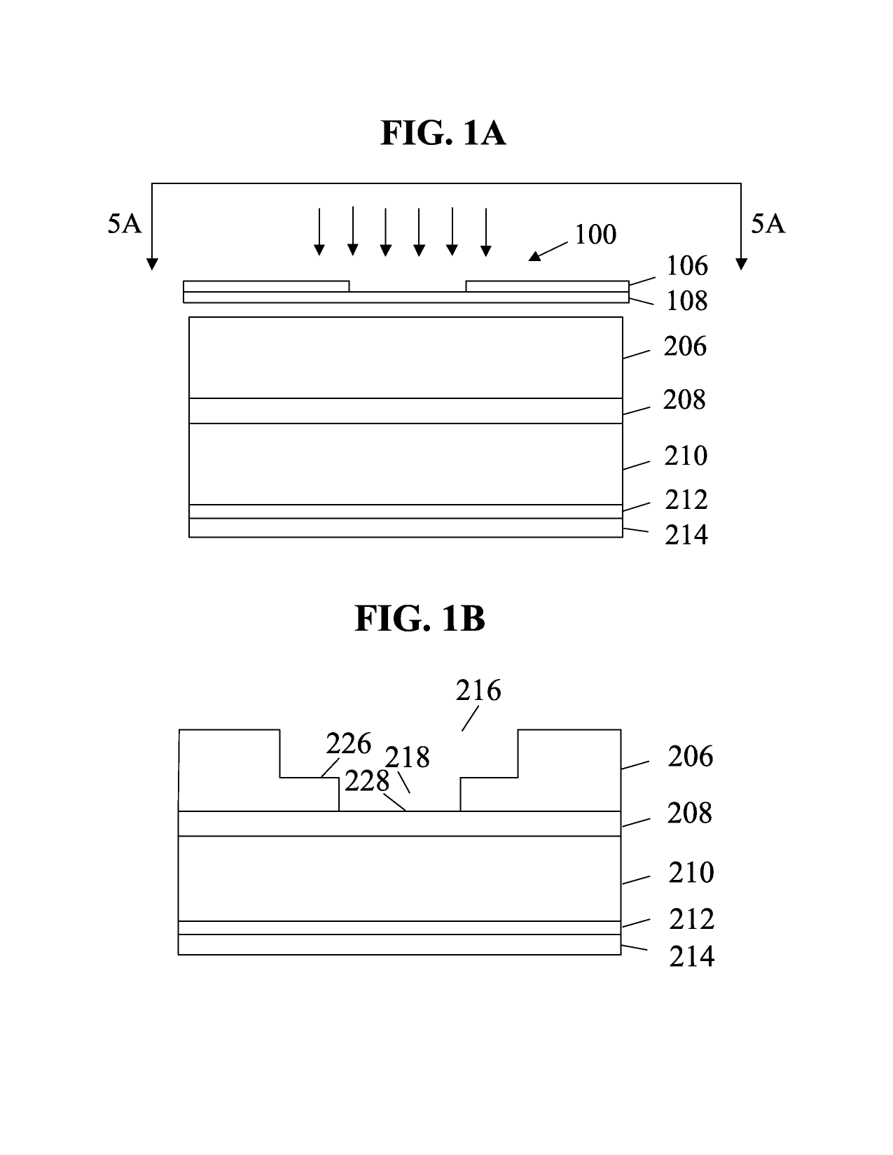

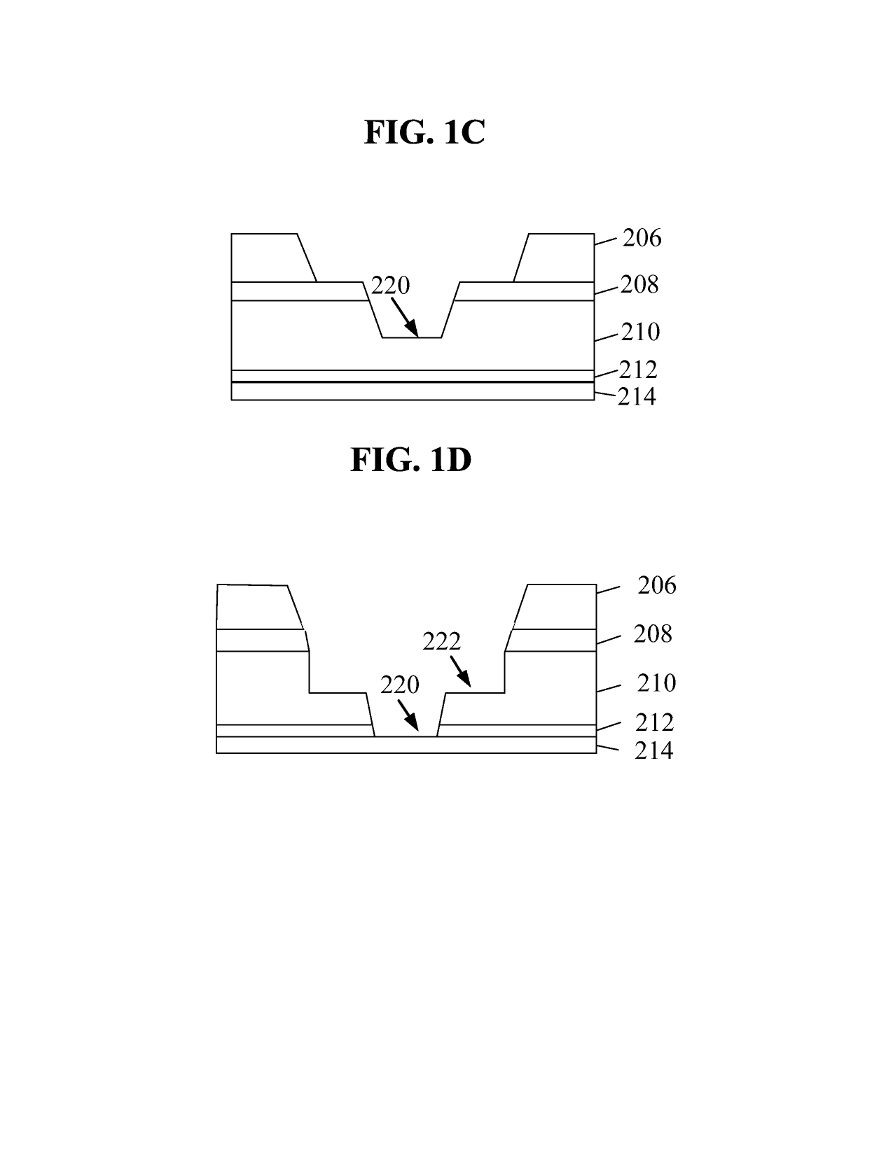

One embodiment, as shown in FIG. 1A, is a method comprising providing at least one dielectric layer (e.g., IMD layer) 208-212 above a semiconductor substrate 214, the at least one dielectric layer 208-212 having a top surface and a bottom surface. A photoresist layer 206 may then be formed on the top surface of the at least one dielectric layer 208-212. A single photomask 100 having at least one first pattern corresponding to a conductive via and at least one second pattern corresponding to a conductive trace may then be provided. The photoresist layer 206 may then be patterned using the single photomask 100, for forming a trench 216 in the photoresist 206 corresponding to the conductive trace and an opening in a bottom surface of the trench 216 corresponding to the via 218 with a single photo exposure step, the bottom surface of the trench 216 being between a bottom of the photoresist layer 206 and a top of the photoresist layer 206. Then etching may be conducted on the dielectric 208-212 through the photoresist layer 206 to form the trench 222 and via 220 therein. The first pattern in this method may include a continuous pattern, while the second pattern in this method may include a diffraction pattern, or plurality of apertures. This embodiment may further comprise, after the exposing step: removing a first soluble portion of the photoresist 206 to form the opening corresponding to the via 218; and removing a second soluble portion of the photoresist to form the trench 216 in the photoresist. The substrate may include a stop layer 214 comprising, for example, silicon carbide, the bottom surface of the dielectric layer 208-212 contacting the stop layer 214. The photoresist layer 206 has a thickness that allows patterning the photoresist 206 to form a trench 216 in the photoresist 206. The remaining thickness of the photoresist 206 beneath this trench 216 reduces an amount of IMD material 208-212 etched away beneath the photoresist 206 to form a trench 222 in the IMD 208-212. The photoresist layer 206 of the present method may be at least about 2 microns thick, for example, to achieve this result. The etching step may comprise dry etching.

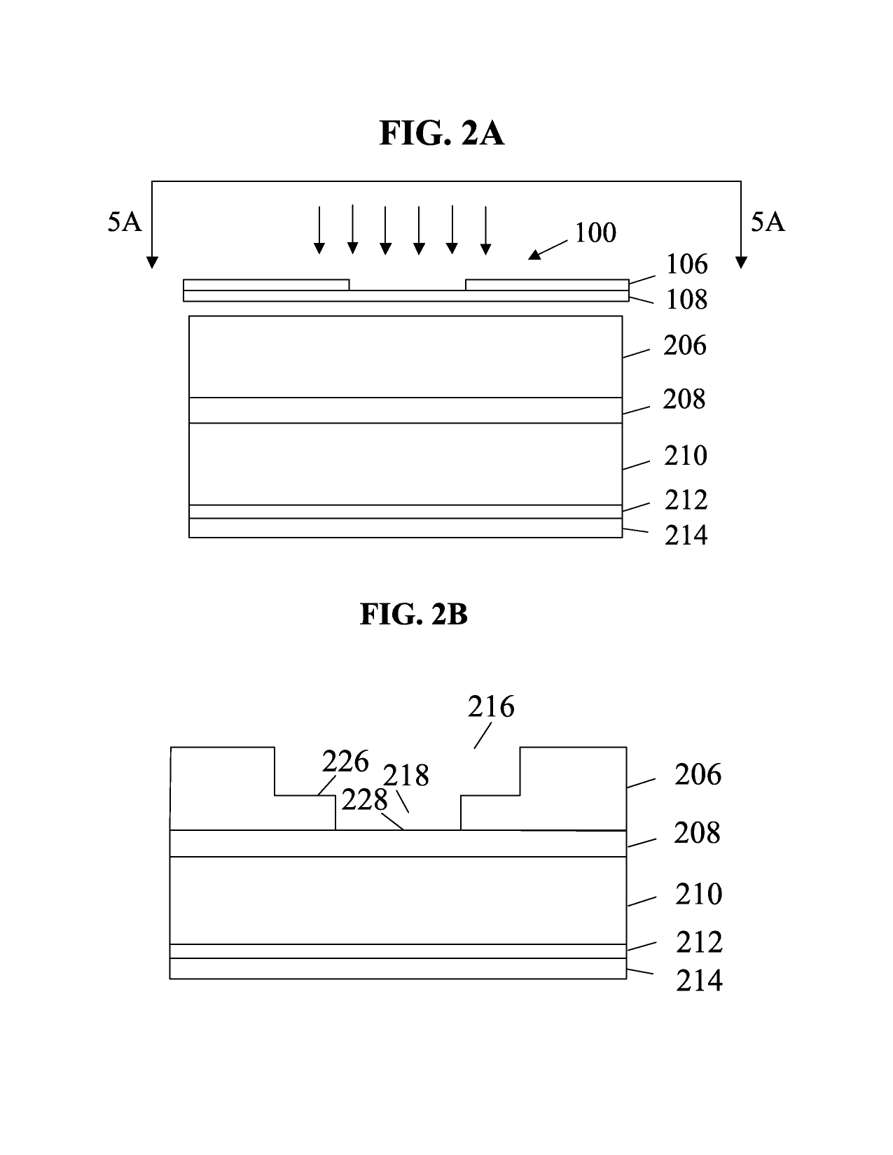

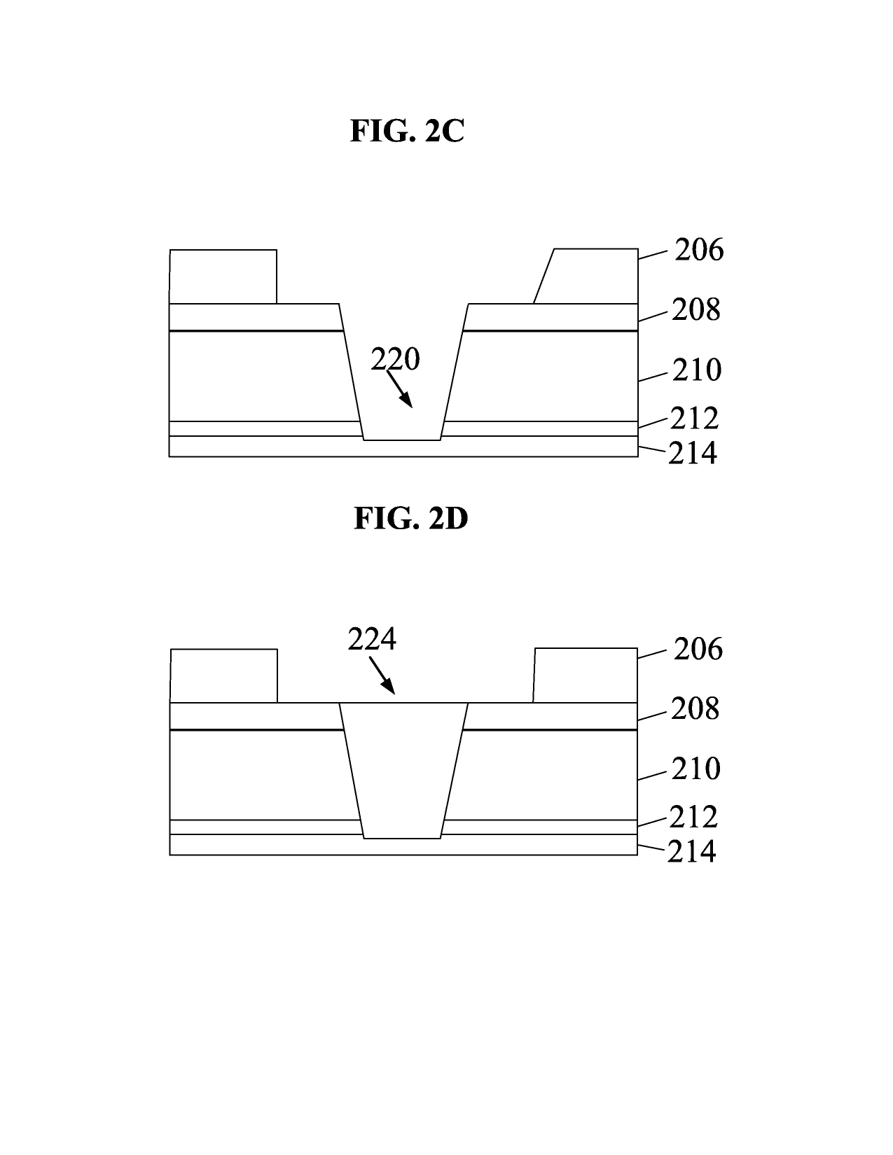

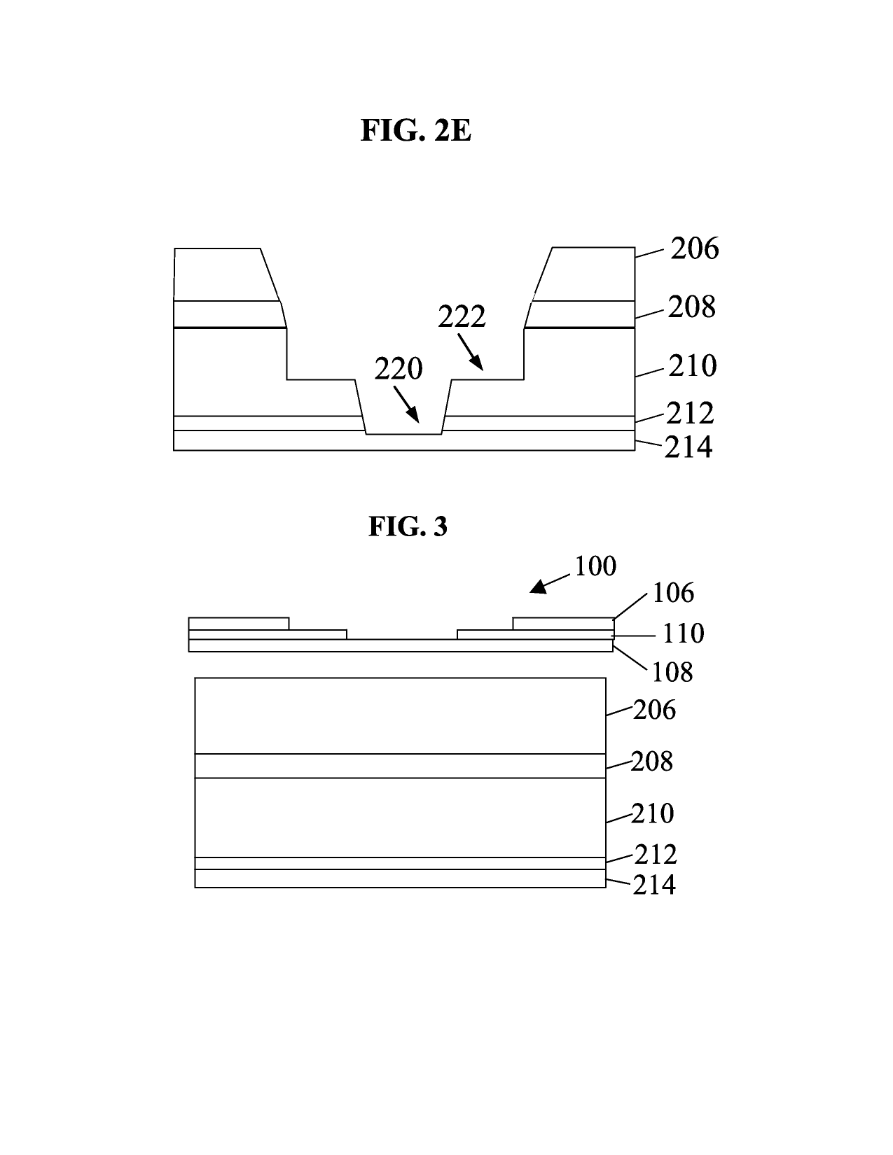

In another embodiment, FIG. 2A, a dual damascene method is provided including forming an opening in a structure by providing at least one dielectric layer 208-212 above a semiconductor substrate 214, the at least one dielectric layer 208-212 having a top surface and a bottom surface. Then forming a photoresist layer 206 on the top surface of the at least one dielectric layer 208-212. Then a photomask 100 is provided with a pattern corresponding to a via and a plurality of apertures corresponding to a conductive trace. An opening is patterned in the photoresist layer 206 through the photomask 100, so that a first portion 218 of the opening corresponding to a via is formed by the pattern. The first portion of the opening corresponding to the via has a first depth 228. A second portion 216 of the opening formed by the plurality of apertures in the form of a trench has a second depth 226 in the photoresist layer 206. Then the photoresist 206 and dielectric 208-212 are etched to form the via 220. Then the via is filled with a plug 224. Then the photoresist 206 is etched through after filling the via 224 to form the trench 222. The plug 224 may be removed after forming the trench 222. The present method may use dry etching to increase the first and second depths, 228 and 226, respectively.

For example, FIGS. 1A-1B and 2A-2B shows exemplary methods for forming a via opening 220 and a trench 222 in an interconnect structure using only one photomask 100 and one photolithography or photo-etching step. By reducing the number of photomasks used in BEOL processing, the method allows the BEOL cycle time and cost to be reduced about 13% to 23%.

In some embodiments of this process, as shown in FIGS. 1A and 2A, a stop layer 214 is provided. This stop layer 214 may be made from silicon carbide or the like. On top of the stop layer 214 one or more dielectric layers 208-212, such as IMD material 210, are provided such that the bottom surface of the dielectric layer 212 contacts the stop layer 214. These dielectric layers 208-212 may be disposed on top of the stop layer 214 using physical vapor deposition, chemical vapor deposition, electrochemical deposition, molecular beam epitaxy, atomic layer deposition, as well as other methods known to a person of skill in the art. These dielectric layers 208-212 may include an inorganic oxide, an organic oxide, oxy-nitride, nitride, a low-κ dielectric material, hydrogen silsesquioxane, methyl silsesquioxane, black diamond, fluorinated silica glass, phosphosilicate glass, poly-tetrafluoroethylene, benzocyclobutene, tetra-ethyl-ortho-silicate, a hard breakdown layer, or a nitrogen-free antireflective layer. In one embodiment, layer 214 is silicon carbide, layer 212 is tetraethyl orthosilicate (“TEOS”), layer 210 is a low-κ dielectric material such as “BLACK DIAMOND”® low-K dielectric from Applied Materials, of Santa Clara, Calif., and layer 208 is a nitrogen free anti-reflective layer (“NFARL”).

A photoresist layer 206 is formed above the IMD layer 210. In the embodiment of FIG. 1A, the photoresist layer 206 is formed on the NFARL layer 208, but in other embodiments, the photoresist layer is formed directly on the IMD layer 210. The photoresist layer 206 may be applied as a liquid and spin-coated for a uniform thickness. The spin coating may be performed at about 1200 to 4800 rpm for about 30 to 60 seconds. The thickness of the photoresist layer 206 may be about 2 microns, but may be more or less depending on the exposure tool type being used, the wavelength of the light being used, the photoresist material 206 being used, the depth of the trench 222 and via 220 desired, and the like. A person of ordinary skill in the art can readily determine the appropriate amount of photoresist 206 by routine experimentation. The photoresist 206 is a light-sensitive material that should have a low resolution (good non-fully-exposed photoresist thickness uniformity (PR U %) and large cadmium loss during ashing), low sensitivity (good non-fully-exposed PR U % and a long exposure time), heat stability (etch-resistance related with, preferably, no post-development baking required), and adhesion (etch-resistance related). The photoresist 206 may be made of poly(methyl methacrylate), poly(methyl glutarimide), phenol formaldehyde resin, SU-8 and the like. The PR U % may be calculated using the following formula:

$$P R U \% = \frac{\begin{matrix}Photoresist thickness maximum - \\ Photoresist thickness minimum\end{matrix}}{Photoresist thickness average} \times 2$$

As shown in FIGS. 1A and 2A, a single photomask 100 with at least one pattern or aperture is provided, such that when light is then shone through the photomask 100, the photoresist layer 206 is patterned to form a hard mask having a trench 216 (corresponding to a conductive trace) and/or an opening 218 (corresponding to a via) by photolithography in a single photo exposure step, as shown in FIGS. 1B and 2B. The average intensity of the light passed through the apertures is less than the average intensity of the light passed through opening 218. Thus, exposure though the continuous opening renders the photoresist soluble to a greater depth (first depth 228); the exposure through the plurality of apertures only transforms (renders soluble) the photoresist beneath the apertures to a shallow depth (second depth 226). The apertures may be in the form of slits, curved slits, 2-dimensional arrays, circles, squares, rectangles, or the like. After the exposure, the soluble portion of the photoresist 206 is removed leaving the trench 216 and via 218 in the photoresist 206. After the photo exposure step, a first soluble portion of the photoresist 206 may be removed to form a via opening 220 and a second soluble portion of the photoresist 206 may be removed to form a trench opening 222. The photoresist 206 may be removed by a solvent (e.g., acetone, 1-Methyl-2-pyrrolidon, dimethyl sulfoxide), by use of alkaline solutions, amine-solvent mixtures, by O₂-plasma combustion, ashing and/or similar methods.

The underlying IMD layer 208-212 can then be etched through this hard mask to form the corresponding trench 222, as shown in FIGS. 1D and 2E, and via 220, as shown in FIGS. 1C and 2C, in the IMD layer 208-212. Although FIGS. 1C and 1D show two successive stages of etching, the etching may optionally be performed in a single etch step. The photoresist material 206 remaining beneath the photoresist trench 216 reduces the amount of IMD material 210 etched away, relative to the amount of IMD material etched beneath the continuous opening in the photoresist 206. The result, as shown in FIGS. 1D and 2E, is formation of a trench 222 and a via 220 in the IMD 208-212. Alternatively, at least one pattern in the photomask 100 is a diffraction pattern or plurality of apertures. The patterning is used to form a trench 216, as shown in FIGS. 1B and 2B corresponding to an opening 218 in the bottom of the trench 216, corresponding to a via or first depth 228 in the photoresist, and a conductive trace or a second depth 226 in the photoresist. The trench pattern has a trench bottom surface 226 in between the bottom of the photoresist layer 206 and the top of the photoresist layer 206. The pattern is then etched through the photoresist layer 206 to form a via 220, as shown in FIGS. 1C and 2C, and a trench 222, as shown in FIGS. 1D and 2E, in the dielectric layer(s) 208-212. The etching of the via 220 and the trench 222 may be done simultaneously or in separate etching steps. If the etching of the via 220 and the trench 222 are done separately, the via opening 220 may be etched to some depth above the stop layer 214 in the dielectric layer(s) 208-212, as shown in FIG. 1C. Then trench 222 and via 220 are dry etched to increase the depth of both the trench 222 and via 220, until the via 220 reaches the stop layer 214 as shown in FIGS. 1D and 2E. Dry etching occurs when a plasma (“dry”) chemical agent removes the layers of the substrate where it is unprotected by a photoresist.

Alternatively, as shown in FIG. 2C, the via opening 220 may be etched to the stop layer 214 and then, as shown in FIG. 2D, plugged with a photoresist plug 224 prior to etching the trench opening 222 as shown in FIG. 2E. The plug 224 may then be removed after forming the trench 222. The via or first depth 220 and trench or second depth 222 may be made using dry etching.

Once the via and trench are formed in the IMD 210, they can then be filled with copper interconnect materials by sputtering, and planarized by CMP. Filling of the via and the trench may be done simultaneously.

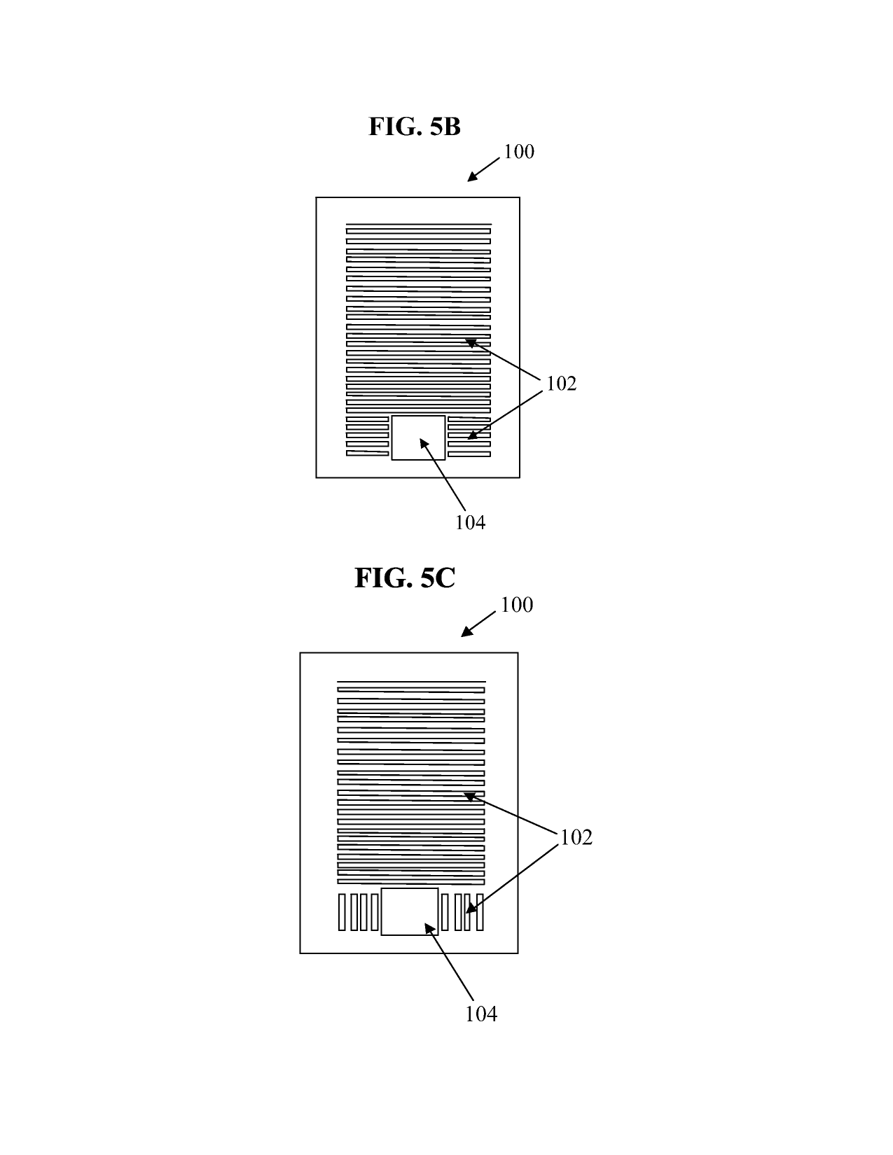

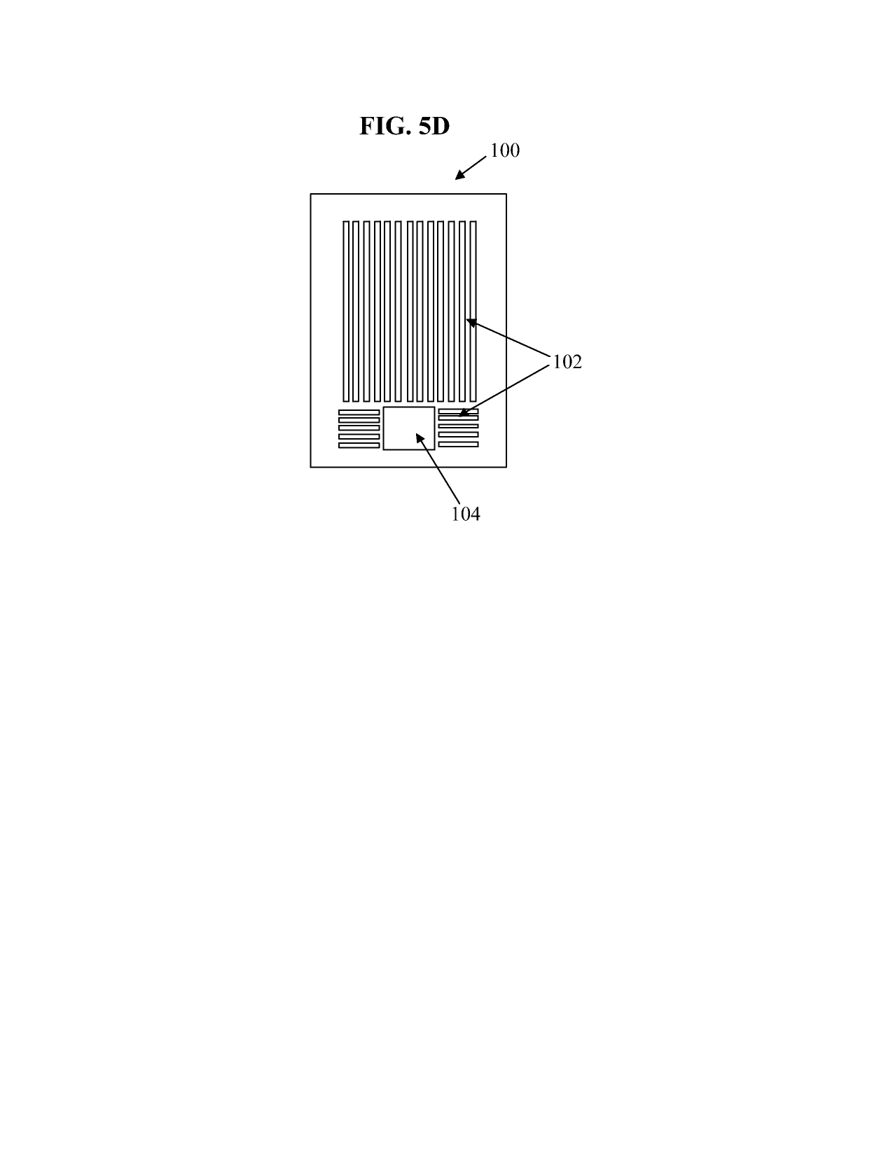

A photomask 100, suitable for patterning the photoresist 206 in the manner described above, is shown in FIGS. 5A-5D. Any of the photomasks in FIGS. 5A-5D may be used in BEOL processes, such as in forming the metal layers M2, M3, etc. In one embodiment, the photomask 100 comprises at least one first pattern 104 configured to expose a photoresist for forming a via in an IMD material and at least one second pattern 102 configured to expose the photoresist for forming a line pattern of a line layer in the IMD material.

The first pattern 104 on the photomask 100 may be continuous, such as an opening, and may correspond to a conductive via. The continuous first pattern 104 provides light of full intensity for exposing the photoresist beneath the first pattern 104 more deeply than the photoresist beneath the second pattern 102. The pattern 104 may be used to pattern or expose a photoresist material for forming a “via” or deeper opening in the photoresist material.

The second pattern 102 may include a plurality of apertures or diffraction grid throughout a length of the line pattern. In some embodiments, the second pattern comprises a plurality of parallel slits, sized and spaced so that the photoresist regions beneath the slit pattern or diffraction grid of the second pattern 102 are exposed to light of reduced intensity (relative to the intensity of light passing through a continuous opening of the mask). The reduced intensity light results in a relatively shallow exposed portion of the photoresist at the surface. The second pattern 102 may include one or more slits oriented in such a way as to form a pattern that may later be made into a trench.

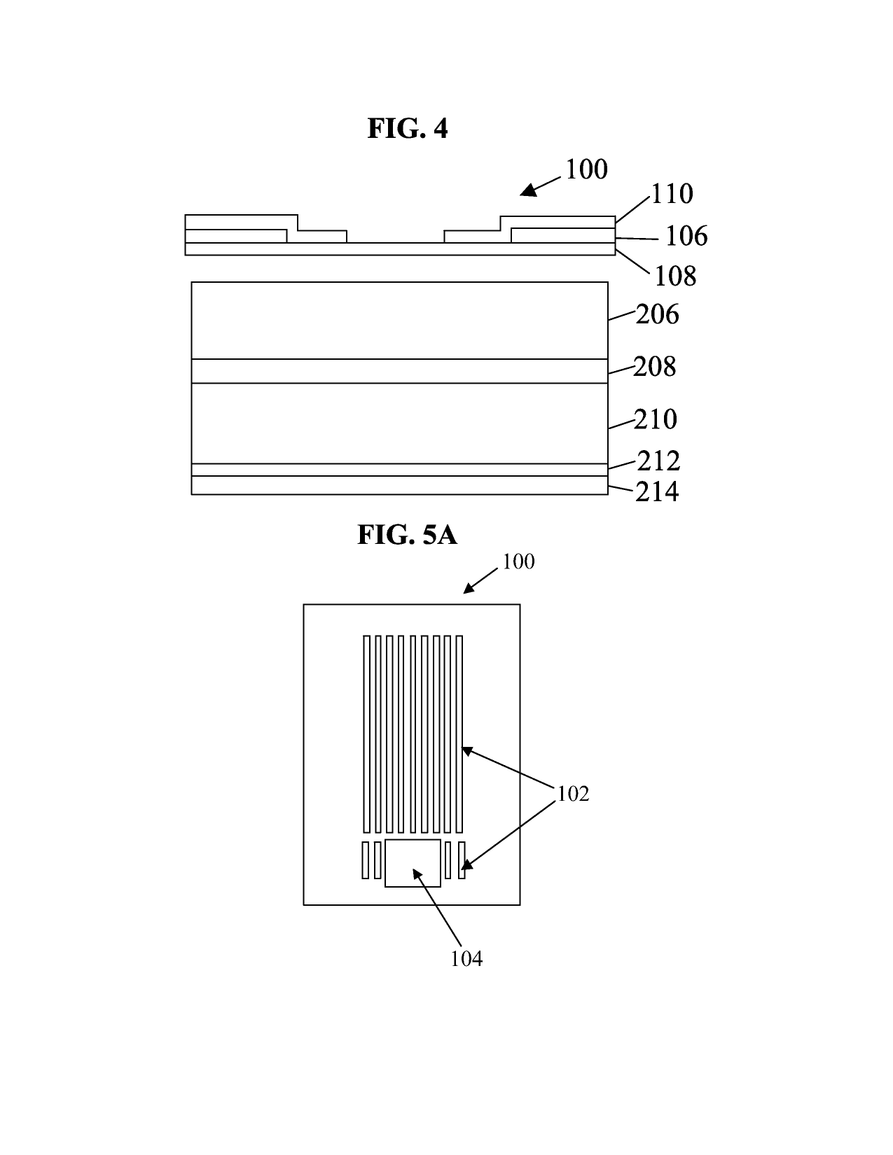

The photomask 100 may include an opaque plate and may made of multiple layers. As shown by the section line in FIGS. 1A and 2A, the photomask 100 of FIGS. 5A-5D may be made of two layers 106-108. Similarly, FIGS. 3 and 4 show photomasks 100 made with three layers 106-110. These layers are made from materials suited for exposing a photoresist through photolithography, such as quartz, chromium, molybdenum silicate, and the like. In one embodiment, layer 106 may be chromium, layer 108 may be quartz, and layer 110 may be molybdenum silicate.

The slits 102 may run length-wise across the photomask, as shown in FIG. 5A, width-wise across the photomask, as shown in FIG. 5B, or a combination of length-wise and width-wise, as shown in FIGS. 5C-5D. The width of the trench 216 formed in the photoresist will be defined by the semiconductor fabrication parameters and may depend on process conditions, such as photoresist taper, photoresist ash recipe, and so forth. The size and number of the slits 102 may depend on the exposure tool type being used, the wavelength of the light being used, the photoresist material being used, and the like.

As shown by the section lines in FIGS. 1A and 2A, beneath the portion of the photomask 100 having the first (continuous, no-aperture) pattern 104, the received photo energy of the photoresist where the opening 218 is to be formed will be strong enough to transform the photoresist (i.e., render the photoresist soluble) to a greater depth below the top surface. After the photoresist is cleaned post-development, the opening in the 218 photoresist corresponding to the first pattern is suitable for forming a via opening in the underlying IMD. Beneath the portion of the photomask having the second (aperture) pattern 102, the received photo energy of the photoresist will be reduced and transforms (i.e., renders soluble) a shallower portion of the photoresist, or a trench pattern. For example, a slit that is wider than the wavelength of the light being used may produce interference effects, causing a smaller diffraction pattern. Possible wavelengths for use with the photomask of the present application include those for use in semiconductor fabrication, such as but not limited to 365 nm, 248 nm, 193 nm, and the like. A person of ordinary skill in the art can readily determine different sizes, shapes, and numbers of apertures 102 in the photomask 100 for forming an appropriate trench in the photoresist that can subsequently be used to form a trench in the IMD layer for conductive traces of any given critical dimension using a given photoresist material, through routine experimentation.

A number of embodiments of the invention are described herein. Nevertheless, it will be understood that various modifications may be made without departing from the spirit and scope of the disclosure. Accordingly, other embodiments are within the scope and range of equivalents of the following claims.

1. A method comprising:
providing at least one dielectric layer above a semiconductor substrate, the at least one dielectric layer having a top surface and a bottom surface;
forming a photoresist layer on the top surface of the at least one dielectric layer;
providing a single photomask having at least one first pattern corresponding to a conductive via and at least one second pattern corresponding to a conductive trace;
patterning the photoresist layer using the single photomask, for forming a trench in the photoresist corresponding to the conductive trace and an opening in a bottom surface of the trench corresponding to the via with a single photo exposure step, the bottom surface of the trench being between a bottom of the photoresist layer and a top of the photoresist layer; and
etching the dielectric through the photoresist layer to form the trench and via therein.

2. A method of claim 1, wherein the first pattern includes a continuous pattern.

3. A method of claim 1, wherein the second pattern includes a diffraction pattern.

4. The method of claim 1, further comprising, after the exposing step:
removing a first soluble portion of the photoresist to form the opening; and
removing a second soluble portion of the photoresist to form the trench.

5. A method of claim 1 wherein the substrate includes a stop layer comprising silicon carbide, the bottom surface of the dielectric layer contacting the stop layer.

6. A method of claim 1 wherein the photoresist layer is at least about 2 microns.

7. A method of claim 1 wherein the etching comprises dry etching.

8. A method for forming an opening in a dual damascene structure comprising
providing at least one dielectric layer above a semiconductor substrate, the at least one dielectric layer having a top surface and a bottom surface;
forming a photoresist layer on the top surface of the at least one dielectric layer;
providing a photomask with a plurality of apertures corresponding to a conductive trace and a pattern corresponding to a via;
patterning an opening in the photoresist layer through the photomask, so that a portion of the opening formed by the pattern has a first depth and a portion of the opening formed by the plurality of apertures has a second depth in the photoresist layer;
etching through the photoresist and dielectric to form the via;
filling the via with a plug; and
etching through the photoresist after filling the via to form the trench.

9. The method of claim 8, further comprising removing the plug after forming the trench.

10. A method of claim 8 wherein the substrate includes a stop layer comprising silicon carbide, the bottom surface of the dielectric layer contacting the stop layer.

11. A method of claim 8 wherein the photoresist layer is at least about 2 microns.

12. A method of claim 8 wherein the patterning is created by diffraction.

13. A method of claim 8 wherein dry etching is used to increase the depth of the first and second depths.

14-20. (canceled)

21. A method of claim 1, wherein the second pattern includes a plurality of apertures.

22. A method of claim 21, wherein the plurality of apertures are in the form of slits, curved slits, 2-dimensional arrays, circles, squares, or rectangles.

23. A method of claim 21, wherein the plurality of apertures run length-wise, width-wise or both length-wise and width-wise across the photomask.

24. A method of claim 4, wherein the first and second soluble portions of the photoresist are removed by a solvent, alkaline solution, amine-solvent mixtures, or O₂-plasma combustion.

25. A method of claim 5, wherein the etching step further comprises:
etching the via to a depth above the stop layer; and
etching the trench and via to increase the depth of both until the via reaches the stop layer.

26. The method of claim 1 further comprising, after the etching step:
filling the trench and via with copper interconnect materials; and
planarizing.

27. The method of claim 8 further comprising, after the etching step:
filling the trench and via with copper interconnect materials; and
planarizing.
